(19) United States
(12) Patent Application Publication
(10) Pub. No.: US 2006/0261847 A1
(43) Pub. Date: Nov. 23, 2006

(54) Semiconductor integrated circuit device

(75) Inventor: Yoshio Kaneko, Chiba (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Minato-ku (JP)

(21) Appl. No.: 11/434,869

(22) Filed: May 17, 2006

(30) Foreign Application Priority Data
May 18, 2005 (JP) 2005-145846

(51) Int. Cl. H03K 19/173

(52) U.S. Cl. 326/37

(57) ABSTRACT

A semiconductor integrated circuit device includes a semiconductor integrated circuit base in which one of a gate array unit and a complex logic unit is formed, a connection unit provided on the semiconductor integrated circuit base, and an IP (Intellectual Property) unit which is selectively connected through the connection unit and has a predetermined function.

### CROSS-REFERENCE TO RELATED APPLICATIONS

This application is based upon and claims the benefit of priority from the prior Japanese Patent Application No. 2005-145846, filed on May 18, 2005: the entire contents of which are incorporated herein by reference.

### BACKGROUND OF THE INVENTION

1. Field of the Invention

The present invention relates to a semiconductor integrated circuit device formed of a gate array unit including an IP (Intellectual Property) unit and the like.

2. Description of Related Art

ASICs (Application Specific Integrated Circuits) have recently been adopted in a wide range of fields.

As a prior-art example of an ASIC, a semiconductor integrated circuit device which includes a gate array unit with a plurality of transistors and an IP (Intellectual Property) unit having a predetermined function is disclosed in, e.g., U.S. Pat. No. 6,624,492.

The device of the prior-art example has an IP unit and a gate array unit formed on a common semiconductor substrate. With this configuration, the device can meet the wide range of needs (demands) of customers or the marketplace.

Meanwhile, there are different needs for the IP unit, for example, a memory device, such as an EEPROM (Electrically Erasable Programmable ROM), DRAM (Dynamic RAM), or SRAM (Static Random Access Memory), and different needs for the gate scale of the gate array unit.

Accordingly, to sufficiently satisfy all specifications in the device of the prior-art example, the number of matrixes to be developed as semi-finished products for which upper layer mask processing is left to be performed needs to be as large as the sum of their scale needs.

When manufacturing an ASIC relevant to the needs of customers or the marketplace, therefore, a standardized circuit for an IP unit is prepared in advance. Two or three lower aluminum layers of such an ASIC can be manufactured using the same standard mask.

Several upper aluminum layers of this ASIC can be changed depending on the design, which allows quick supply of products relevant to the needs. In this case, because the function of the IP unit such as an EEPROM or the like is determined by its standard mask portion, it is necessary to develop a large number of masks for IP units of different types and with different scales and the like.

The device of the prior-art example is intended to meet the wide range of needs of customers using the gate array unit including the IP unit. In this case, in the device of the prior-art example, the bit configuration of a memory as an example of the IP unit can be changed at an upper aluminum layer, but its memory capacity cannot be changed.

In the device of the prior-art example, the circuit scale of the gate array unit also cannot be changed. To meet the wide range of needs of customers or the like, it is necessary to develop a large number of matrixes, as will be described below.

For example, consider providing an IP-combined semiconductor integrated circuit device relevant to the needs of customers in which one CPU (Central Processing Unit) can serve as an IP unit and which includes the CPU, memory devices of different types and with different capacities, and a gate array unit.

Assume that each matrix is equipped with one CPU and that there is a need for gate array units with IP units which have respective combinations of one of ten gate scales, one of ten SRAM capacities, one of ten EEPROM capacities, and one of ten DRAM capacities. In this case, it is necessary to prepare 10,000 (=10×10×10) types of matrixes.

Development of such a huge number of types of matrixes requires a huge amount of materials and funds and a huge number of developers. Accordingly, there is a demand for a technique or device which can reduce the number of matrixes.

### BRIEF SUMMARY OF THE INVENTION

A semiconductor integrated circuit device according to one aspect of the present invention includes a semiconductor integrated circuit base in which one of a gate array unit and a complex logic unit is formed, a connection unit provided on the semiconductor integrated circuit base, and an IP (Intellectual Property) unit which is selectively connected through the connection unit and has a predetermined function.

### BRIEF DESCRIPTION OF THE DRAWINGS

FIG. 1 is a plan view showing an IP-combined gate array device according to a first embodiment of the present invention;

FIG. 2 is a side view of FIG. 1;

FIG. 3 is an explanatory view showing an IP-combined gate array matrix and the like prepared in advance to manufacture the IP-combined gate array device of FIG. 1;

FIG. 4 is a plan view showing an IP-combined gate array device according to a first modification of the first embodiment;

FIG. 5 is a front view of FIG. 4;

FIGS. 6A and 6B are a plan view showing IP-combined gate array device matrixes according to a second modification of the first embodiment;

FIG. 7 is a plan view showing an IP-combined gate array device according to a third modification of the first embodiment;

FIG. 8 is a side view of FIG. 7;

FIG. 9 is a plan view showing an IP-combined structured ASIC device according to a second embodiment of the present invention;

FIG. 10 is a side view showing part of FIG. 9 in cross section;

FIG. 11 is a plan view showing an IP-combined gate array device according to a third embodiment of the present invention;

FIG. 12 is a side view of FIG. 11;

FIG. 13 is a plan view showing an IP-combined gate array device according to a modification of the third embodiment; and

FIG. 14 is a side view showing part of FIG. 13 in cross section.

### DETAILED DESCRIPTION OF THE EMBODIMENTS OF THE INVENTION

Embodiments of the present invention will be explained below with reference to the drawings.

### First Embodiment

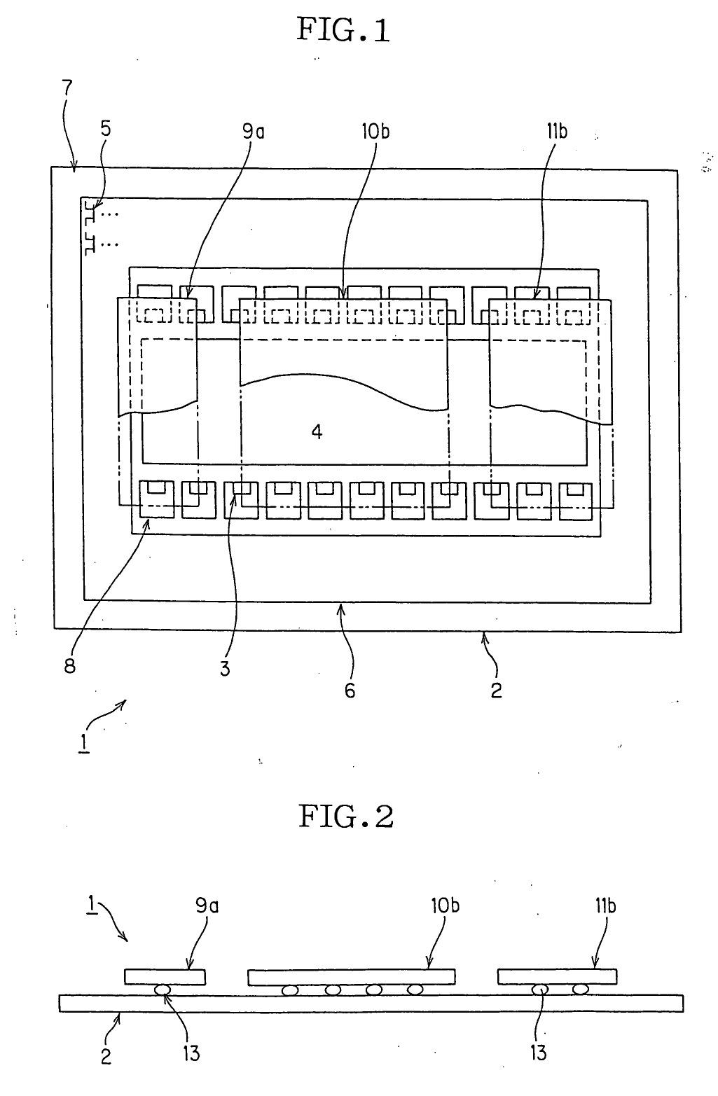

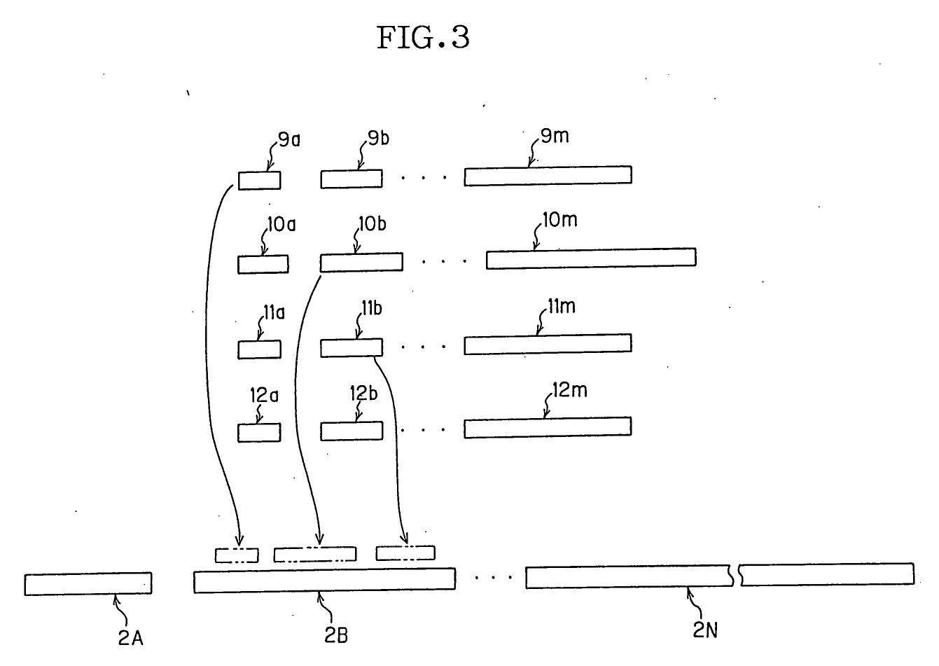

FIGS. 1 to 3 relate to a first embodiment of the present invention. FIG. 1 shows a plan view of the configuration of an IP-combined gate array device according to a first embodiment of a semiconductor integrated circuit device of the present invention; FIG. 2, a side view of FIG. 1; and FIG. 3, a system including an IP-combined gate array matrix and the like prepared in advance to manufacture the IP-combined gate array device of FIG. 1.

An IP-combined gate array device 1 according to the first embodiment of the present invention shown in FIGS. 1 and 2 has, e.g., a two-stage MCP (Multi Chip Package) structure and has an IP-combined gate array unit 2 as a lower-side semiconductor integrated circuit base unit (to be abbreviated as an IC base unit) or lower-side IC chip.

Bump pads 3 are provided on the upper surface of the IP-combined gate array unit 2 as connection units which allow selective connection of a plurality of types of IC units to the upper surface.

The IP-combined gate array unit 2 includes a CPU (Central Processing Unit) 4 which has a function capable of serving many purposes depending on the program as an IP unit having a predetermined function manufactured by a large-scale semiconductor manufacturing process near the center of the semiconductor substrate, a gate array unit 6 formed by closely laying a plurality of transistors 5 around the CPU 4, and an I/O buffer unit 7 formed around the gate array unit 6 and, e.g., along the rectangular periphery of the IP-combined gate array unit 2.

The I/O buffer unit 7 is composed of a plurality of buffers. An I/O terminal pad (not shown) is arranged for each of the buffers. Each I/O terminal pad is electrically connected to an external terminal (not shown) outside by bonding or the like.

The plurality of bump pads 3 for connecting an upper-side chip are provided between the longitudinal sides of the CPU 4 arranged at the center and the gate array unit 6 provided along the sides. The bump pads 3 are connected to respective I/O buffers 8. Note that the I/O buffers 8 are electrically connected to the gate array unit 6 or CPU 4.

Upper-side chips which include IPs having various functions (in the shown specific example, an SRAM 9a, an EEPROM 10b, and a DRAM 11b are used as examples of memory device IPs having a function of storing information) are electrically connected or mechanically fixed by bumps 13 (see FIG. 2) to the IP-combined gate array unit 2 as the lower-side chip at the bump pads 3 provided on the upper surface of the IP-combined gate array unit 2.

The bump pads 3 are formed, e.g., along the longitudinal sides of the CPU 4 such that they opposite at a predetermined distance, and the distance between the opposing bump pads 3 is set to be the distance between opposing pads serving as connection units of the upper-side chips.

Note that the numbers of the bump pads 3 and I/O buffers 8 shown in FIG. 1 are smaller than the actual numbers due to space limitations. Each bump pad 3 and the corresponding I/O buffer 8 in FIG. 1 correspond to four to ten pairs of the bump pad 3 and the I/O buffer 8.

The IP-combined gate array unit 2 as the lower-side chip constituting the IP-combined gate array device 1 shown in FIGS. 1 and 2 is selected and used from among a plurality of IP-combined gate array matrixes 2A, 2B, . . . , 2N in accordance with the needs of customers or the like. The IP-combined gate array matrixes 2A to 2N have the respective gate array units 6 with different scales (and each has the bump pads 3, the number of which corresponds to the scale), as shown in FIG. 3.

These IP-combined gate array matrixes 2A, 2B, . . . , 2N can be prepared by using corresponding masks developed in advance.

More specifically, in the system according to this embodiment, the plurality of IP-combined gate array matrixes 2A to 2N, whose gate array units 6 (each being formed from the transistors 5) have different gate scales, are developed and prepared in advance, as shown in FIG. 3.

In accordance with the needs of customers or the like, a developer (manufacturer) selects an IP-combined gate array matrix 2I (I=A to N) formed by performing a wafer underlayer forming step for a semiconductor substrate, performs a step of wiring the gate array unit 6 and the like of the IP-combined gate array matrix 2I to an upper aluminum layer, and selectively packages a memory device corresponding to the type, storage capacity, and the like required of a memory device.

In other words, in accordance with the needs of customers or the like, a developer uses the IP-combined gate array matrix 2I having the enough gate arrays to meet the needs and selectively packages a memory device corresponding to the type, storage capacity, and the like required of a memory device to be mounted.

The system with this configuration can implement the IP-combined gate array device 1, which can meet a wide range of needs at low cost, by preparing the IP-combined gate array matrixes 2A to 2N, the number of which is small.

Also, a developer can meet a wide range of needs only by developing the IP-combined gate array matrixes 2A, 2B, . . . , 2N. This makes it possible to reduce the number of people and the like required for development and lower the cost of the IP-combined gate array device 1 to be provided.

FIGS. 1 and 2 show the one IP-combined gate array device 1, which is manufactured using, e.g., the IP-combined gate array matrix 2B having enough gate arrays to meet needs, as shown in FIG. 3.

The IP-combined gate array device 1 of FIGS. 1 and 2 is shown to have an exemplary configuration in which the SRAM 9a, EEPROM 10b, and DRAM 11b are selected and mounted as memory devices specified for the IP-combined gate array matrix 2B from among the SRAM 9a to SRAM 9m, the EEPROM 10a to EEPROM 10m, and the DRAM 11a to DRAM 11m. The subscripts atom indicate that there are a plurality of memories of each type. An SRAM, EEPROM, and the like are selected in accordance with needs.

Note that reference numerals 12a to 12m in FIG. 3 denote, e.g., a flash memory, ROM (Read Only Memory), ferroelectric memory, and the like. Although the memories denoted by 12a to 12m are not mounted on the IP-combined gate array device 1 in the shown example, they may be mounted depending on needs.

The operation of this embodiment with the above-described configuration will be explained below. The position of the bump pad connecting each memory device and the IP-combined gate array matrix will be explained first.

High stability is obtained at the time of assembling an MCP when bump pads for a memory device are arranged on the periphery of the memory device. Since the positions of the bump pads for the memory device as an upper chip need to be horizontally equal to those of the corresponding bump pads 3 on the lower chip, they affect the positions of the bump pads 3 and the like on the IP-combined gate array matrixeside.

Generally, when another chip is connected to the IP-combined gate array matrix, the connection is established via corresponding ones of the I/O buffers 8 whose driving current is large, and thus, a large current flows between each I/O buffer 8 and the corresponding bump pad 3. Accordingly, it is preferable in terms of electrical characteristics that each I/O buffer 8 and the corresponding bump pad 3 are arranged near to each other.

Assume a case where the transistors are arranged below the bump pads. If pressure is applied at the time of bump-bonding the upper and lower chips, the transistor elements below the bump pads may be adversely affected. Accordingly, it is desirable not to form circuits below the bump pads.

However, to satisfy these conditions, the circuits need to be formed at the time of forming the gate array matrix, which fixes the positions of the bump pads 3 and the like.

It is desired that a plurality of types of memory devices having different circuit scales can be connected to the IP-combined gate array unit 2.

If bump pads are arranged along the four edges of each memory device, some of the bump pads 3 and I/O buffers 8 need to be arranged at the center of the IP-combined gate array unit 2. This reduces the space in which a circuit such as a CPU is formed.

For this reason, the bump pads 3 are preferably arranged in two groups in parallel in the IP-combined gate array unit 2 such that they oppose the bump pads along two opposing parallel edges of each memory device, as shown in FIG. 1. This configuration has the great advantage that each memory device to be connected is physically stable and that the space between the two groups of bump pads 3 arranged in parallel can be effectively utilized.

Assume a case where (memory device-side) bump pads are formed and arranged along three edges of each memory device. If the memory devices are connected to the IP-combined gate array matrix, the bump pads for the IP-combined gate array matrix may be formed, e.g., on the periphery. In this case, it is only necessary to arrange the bump pads in two lines along two edges of the IP-combined gate array matrix. If each memory device is small, a larger number of bump pads can be conveniently provided by providing bump pads along its three edges than by providing ones along its two edges.

In this embodiment, before manufacturing an IP-combined gate array device which meets the needs of customers or the like, a developer develops the IP-combined gate array matrixes 2A to 2N, whose gate arrays have different scales, for use at the time of manufacture, as shown in FIG. 3.

In this case, the gate array scale and the types, storage capacities, and the like of memory devices to be mounted such as an SRAM, EEPROM, and DRAM are specified as the needs of customers, in addition to the CPU 4.

To meet the needs, the prior-art example requires matrixes, the number of which corresponds to the number of combinations, as IP-combined gate array matrixes. For example, if one of N different gate array scales, one of M different SRAM storage capacities, . . . are specified for one IP-combined gate array matrix, the number of matrixes required corresponds to the number of combinations as huge as N×M× . . . .

In contrast with this, in this embodiment, a developer only needs to prepare the IP-combined gate array matrixes 2A to 2N, which each have the CPU 4 mounted thereon and have different gate array scales, and select and package a memory device of the specified type and with the specified storage capacity.

Therefore, this embodiment can easily and flexibly meet the wide range of needs of customers or the like at low cost. This embodiment also can provide an IP-combined gate array device which meets the needs in a short period of time by preparing the IP-combined gate array matrixes 2A to 2N, the number of which is small.

A first modification of the first embodiment will be explained next.

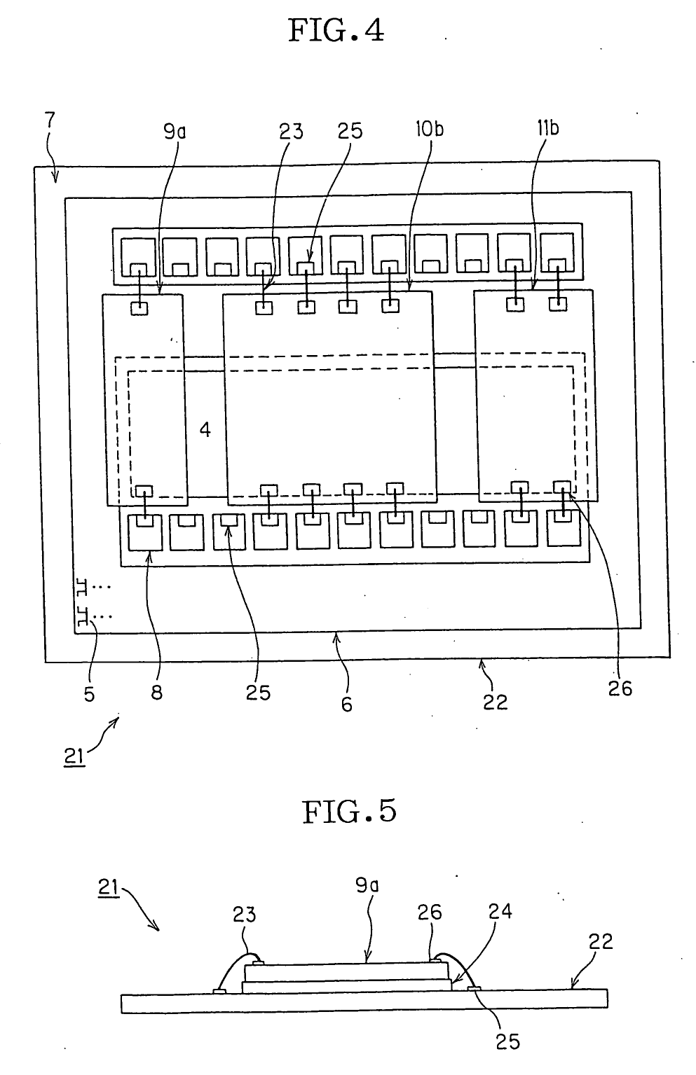

In the above explanation, the bumps 13 are adopted as connection means for connecting the upper-side chips. An IP-combined gate array device 21 may be manufactured using bonding wires 23, as shown in FIGS. 4 and 5.

The IP-combined gate array device 21 has an IP-combined gate array unit 22, an insulating plate 24 (see FIG. 5) arranged on the upper surface of the IP-combined gate array unit 22, and, e.g., the SRAM 9a, EEPROM 10b, and DRAM 11b serving as upper-side chips arranged above the IP-combined gate array unit 22 with the insulating plate 24 inserted between them. The upper-side chips and the IP-combined gate array unit 22 are connected to each other by the bonding wires 23.

In the IP-combined gate array unit 22, one of the two groups of bump pads 3 and I/O buffers 8 arranged between the CPU 4 and the gate array unit 6 around it in the IP-combined gate array unit 2 shown in FIGS. 1 and 2 such that the groups oppose each other is arranged at a distance from its position in FIG. 1. The one group of bump pads 3 and I/O buffers 8 can be used as bonding pads 25 and the corresponding I/O buffers 8.

In FIG. 4, the bonding pads 25 and I/O buffers 8 on the lower side of the sheet surface are formed using the corresponding bump pads 3 and I/O buffers 8 in FIG. 1 without change. Alternatively, the bonding pads 25 and the I/O buffers 8 may be provided by providing the bump pads 3 and I/O buffers 8 upward at a distance from their positions in FIG. 1, like the bonding pads 25 and I/O buffers 8 on the upper side.

Pads 26 serving as connection units provided on the SRAM 9a and the like as upper-side chips are provided on the upper surface, and the pads 26 and their adjacent bonding pads 25 are electrically connected to each other by the bonding wires 23.

In the example shown in FIG. 4, the bonding pads 25 and I/O buffers 8 are provided inside the gate array unit 6. Other portions of the configuration are the same as those explained in the first embodiment, and an explanation thereof will be omitted.

This modification can easily meet the wide range of needs of customers or the like by preparing a plurality of IP-combined gate array matrixes having different gate array scales as the IP-combined gate array unit 22. That is, this modification is different from the first embodiment only in connection means and has almost the same effects as those of the first embodiment.

A second modification of the first embodiment will be explained next.

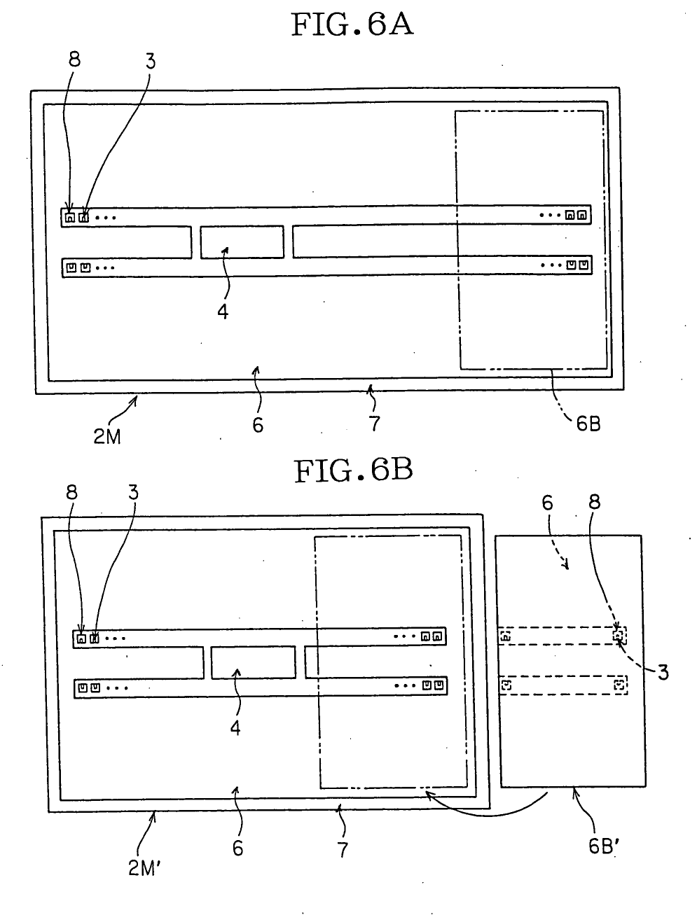

To provide an IP-combined gate array device which meets the wide range of needs of customers or the like, the IP-combined gate array matrix 2M having gate arrays, the number of which is large, needs to be prepared, as shown in, e.g., FIG. 6A. Even in this case, suppression of the size (area) brings about a greater advantage.

For this reason, in a system according to this modification, an IP-combined gate array matrix 2M′ obtained by reducing the size of the IP-combined gate array matrix 2M shown in FIG. 6A by about the size of a gate array matrix 6B (indicated by a chain double-dashed line in FIG. 6A) including some of the bump pads 3 and I/O buffers 8 and a gate array matrix 6B′ corresponding to the gate array matrix 6B are developed and prepared instead of the IP-combined gate array matrix 2M, as shown in, e.g., FIG. 6B.

FIG. 6B shows the gate array matrix 6B′ with the gate array unit 6 formed on its bottom surface (the gate array matrix 6B′ with the orientation when it is mounted on the upper surface of the IP-combined gate array matrix 2M′ as indicated by an arrow).

In this system, the IP-combined gate array matrix 2M′ can be used as the IP-combined gate array matrix 2M′ having a smaller gate array scale than that of the IP-combined gate array matrix 2M. If the number of gate arrays of the IP-combined gate array matrix 2M′ alone is insufficient, the gate array matrix 6B′ is used together.

In this case, it is sufficient for a developer to mount the gate array matrix 6B′ on the IP-combined gate array matrix 2M′ by bump-bonding it at the bump pads 3 on the IP-combined gate array matrix 2M′, as indicated by a chain double-dashed line in FIG. 6B. Actually, the gate array matrix 6B′ is mounted (packaged) after a wiring step is performed. Note that even if the gate array matrix 6B′ is mounted on the IP-combined gate array matrix 2M′, a memory device or the like shown in, e.g., FIG. 1 can be mounted to the left of a portion where the gate array matrix 6B′ is mounted.

This modification makes it possible to make the number of IP-combined gate array matrixes smaller than the first embodiment.

Also, this modification has the effects of the first embodiment and makes it possible to reduce the size (area).

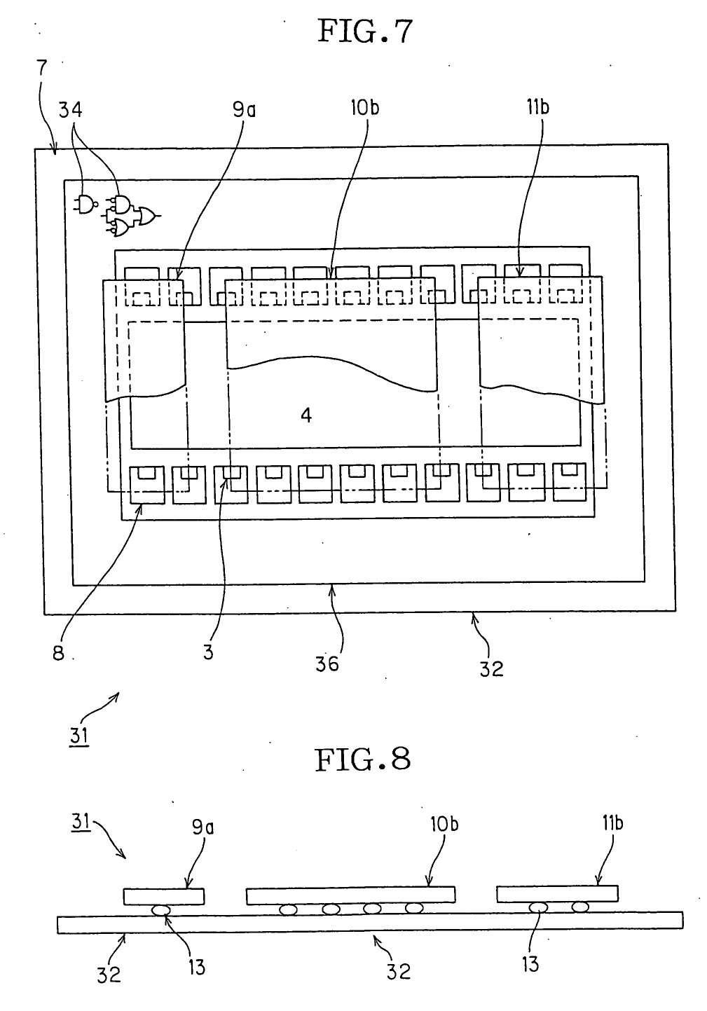

A third modification of the first embodiment will be explained next with reference to FIGS. 7 and 8.

FIGS. 7 and 8 show a plan view and a side view, respectively, of a structured ASIC device 31 according to the third modification. The structured ASIC device 31 adopts an IP-combined complex logic unit (or IP-combined structured ASIC) 32 in which the gate array unit 6 in the IP-combined gate array unit 2 of the IP-combined gate array device 1 shown in FIGS. 1 and 2 is replaced with a complex logic unit 36.

The complex logic unit 36 is composed of complex logic cells 34 shown in FIG. 7 obtained by combining, e.g., a NAND circuit, AND circuit, NOR circuit, and OR circuit, instead of the transistors 5 constituting the gate array unit 6 of FIG. 1. Other portions of the configuration are the same as those of the first embodiment.

In this modification as well, the structured ASIC device 31, which meets a wide range of demands, can be implemented or provided only by preparing a plurality of IP-combined complex logic matrixes (or IP-combined structured ASIC matrixes), instead of the IP-combined gate array matrixes 2A to 2N shown in FIG. 3 of the first embodiment. That is, this modification has almost the same effects as those of the first embodiment.

Note that the complex logic cells 34 are not limited to a NAND circuit and the like shown in FIG. 7, and other logic circuits may be adopted.

The first embodiment has been explained using an example in which the CPU 4 widely used as an IP is formed integrally with the gate array unit 6. This embodiment can also be applied to a case where a memory device IP such as an SRAM instead of the CPU 4 is formed integrally with the gate array unit 6.

As described above, according to this embodiment and its modifications, an IP unit having a predetermined function can be selectively connected to a semiconductor integrated circuit base through a connection unit. This makes it possible to reduce the number of matrixes required to manufacture a semiconductor integrated circuit device and meet a wide range of needs.

### Second Embodiment

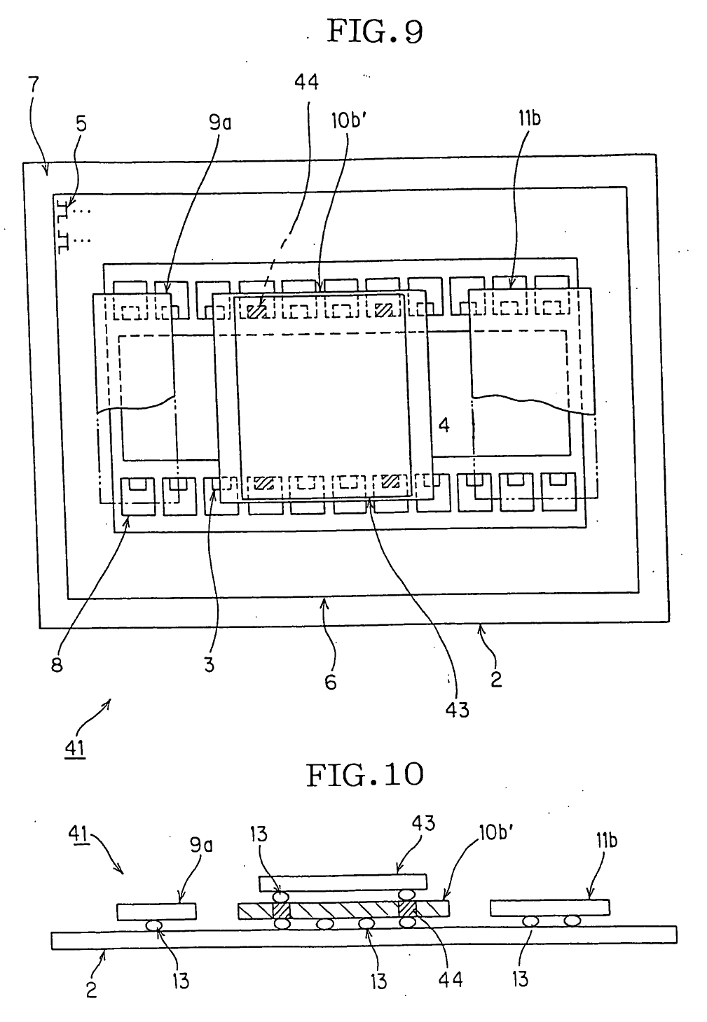

A second embodiment of the present invention will be explained next with reference to FIGS. 9 and 10. FIG. 9 shows a plan view of the configuration of an IP-combined gate array device according to the second embodiment of a semiconductor integrated circuit device of the present invention; and FIG. 10, a side view of FIG. 9. Note that FIG. 10 schematically shows part of FIG. 9 in cross section. More specifically, FIG. 10 schematically shows through holes 44 at an EEPROM 10b′ unit near the center in cross section.

An IP-combined gate array device 41 according to the second embodiment shown in FIGS. 9 and 10 has a three-stage MCP structure obtained by, e.g., stacking an IP chip on the upper-side chips in the IP-combined gate array device 1 of the first embodiment.

In the example shown in FIG. 9, a flash memory 43 is connected as an example of a memory device on the upper surface of the EEPROM 10b′ by bumps 13.

In this case, the through holes (or conductive units) 44 filled with a metal such as aluminum (see FIG. 10) are formed in the EEPROM 10b′ such that the flash memory 43 can be connected.

By connecting the lower end of each through hole 44 to a corresponding one of bump pads 3 on the upper surface of an IP-combined gate array unit 2 by the corresponding bump 13, the upper end of the through hole 44 becomes electrically conductive with the bump pad 3. A portion corresponding to the bump pad 3 is formed at the upper end. The flash memory 43 as the memory device is connected at the portion by the corresponding bump 13, as described above.

Other portions of the configuration are the same as those explained in the first embodiment, and an explanation thereof will be omitted.

As described above, according to this embodiment, an IP unit having a predetermined function can be selectively connected to a semiconductor integrated circuit base through a connection unit. This makes it possible to reduce the number of matrixes required to manufacture a semiconductor integrated circuit device and meet a wide range of needs.

Also, this embodiment makes it possible to suppress an increase in size (area) and reduce the size.

Although not shown, it is apparent that this embodiment can also be applied to a case where a structured ASIC device is formed by replacing a gate array unit with a complex logic unit.

### Third Embodiment

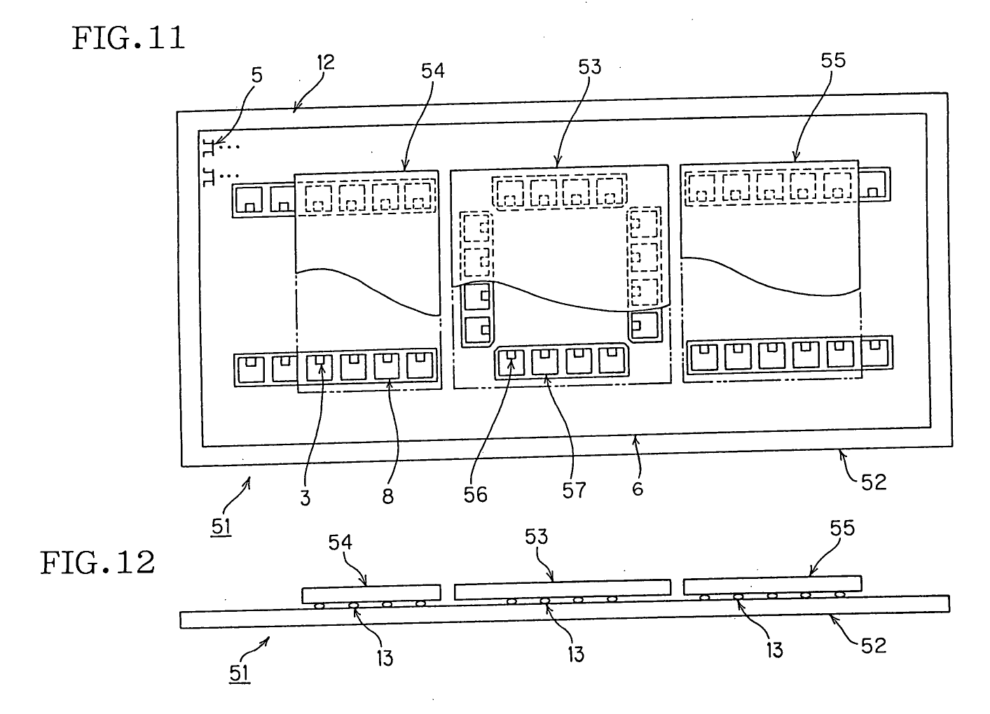

A third embodiment of the present invention will be explained next with reference to FIGS. 11 and 12. FIG. 11 shows a plan view of the configuration of an IP-combined gate array device according to the third embodiment of a semiconductor integrated circuit device of the present invention; and FIG. 12, a side view of FIG. 11.

An IP-combined gate array device 51 according to this embodiment is composed of a gate array unit 52 as a lower-side chip, a CPU 53 mounted on the upper surface of the gate array unit 52, an SRAM 54, and a ferroelectric RAM 55.

The IP-combined gate array device 51 according to this embodiment adopts the gate array unit 52 having a structure in which the CPU 4 as the IP is not integrally formed, in the IP-combined gate array unit 52 as, e.g., the lower-side chip of the first embodiment.

Bump pads 56 and I/O buffers 57 as connection units configured to connect the CPU 53 are provided, e.g., at the center on the upper surface of the gate array unit 52. Bump pads 3 and I/O buffers 8 are provided on both sides to connect a memory device and the like. A gate array unit 6 formed by closely laying transistors 5 is provided around these bump pads and I/O buffers.

Although in the shown example, the bump pads 56 and I/O buffers 57 are arranged, e.g., along a square frame for connecting the CPU 53, the present invention is not limited to this. The bump pads 56 and I/O buffers 57 may be formed along two parallel lines like the bump pads 3 and I/O buffers 8 in the other embodiments and modifications. Bump pads may be provided along three edges of the CPU 53. In this case, the bump pads 56 may be arranged such that they oppose the bump pads provided along the three edges of the CPU 53.

I/O buffers 12 are provided such that they surround the periphery of the gate array unit 6.

In response to the needs of customers or the like, the CPU 53, SRAM 54, and ferroelectric RAM 55 are connected to the upper surface of the gate array unit 52 by bumps 13, as shown in, e.g., FIG. 12.

This embodiment is configured to be capable of meeting the wider range of needs of customers or the like for a CPU, by using one on which the CPU 53 as an IP is not provided as a matrix used to manufacture the IP-combined gate array device 51.

More specifically, if customers or the like has a need for a CPU portion with higher performance in an IP-combined gate array device, it is expected to be potentially difficult for one in which a CPU is formed integrally with the gate array unit 52 to meet the need.

Even in this case, adoption of a structure in which a CPU portion can be mounted later on the gate array portion allows mounting of, e.g., a higher-level compatible CPU having higher functionality than the existing developed CPU 4. This makes it possible to more flexibly provide the IP-combined gate array device 51, which meets required specifications.

As for the CPU portion, high-level compatible CPUs with higher performance are released one after another at relatively short intervals. Adoption of a structure in which a CPU can be selectively mounted on the gate array unit brings about the advantage of a quick response to changes in the market.

As described above, this embodiment has the effects of the first embodiment. More specifically, according to this embodiment, an IP unit having a predetermined function can be selectively connected to a semiconductor integrated circuit base through a connection unit. This makes it possible to reduce the number of matrixes required to manufacture a semiconductor integrated circuit device and meet a wide range of needs.

This embodiment can flexibly cope with a case where there is a demand for a CPU with higher performance in an IP-combined gate array device.

This embodiment can be applied to a structured ASIC device as well formed by replacing the gate array unit 52 with a complex logic unit.

This embodiment makes it possible to implement an IP-combined ASIC device having a structure in which part of the gate array unit 52 is replaced with a complex logic unit.

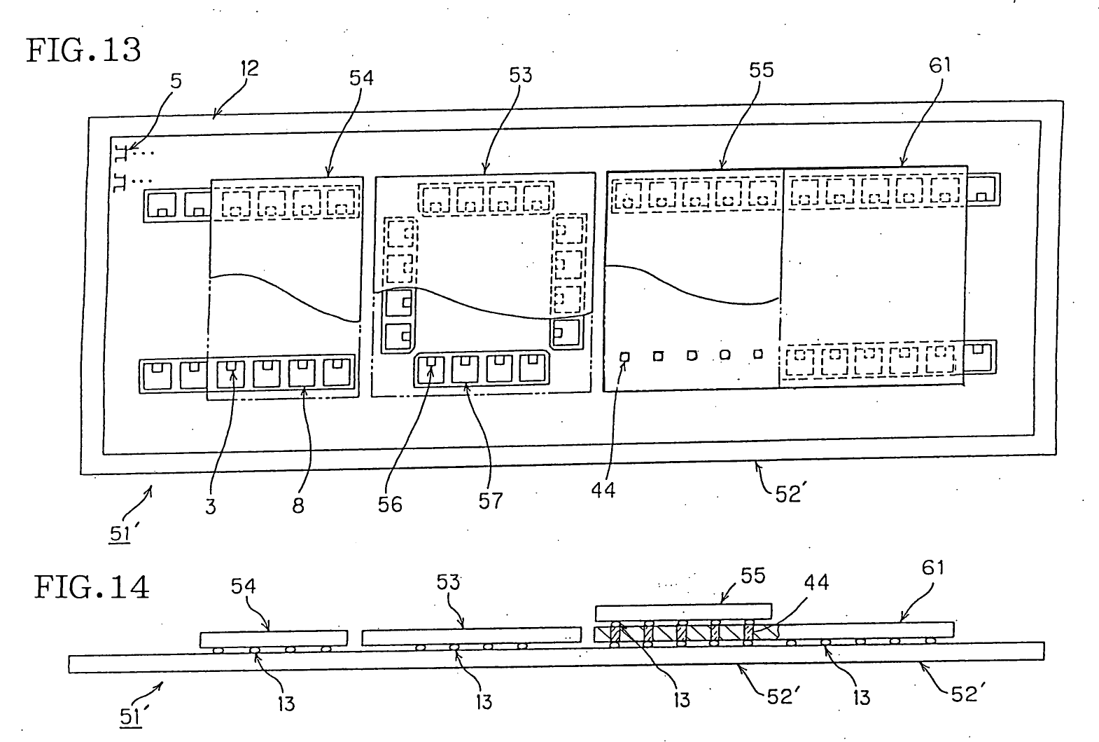

A modification of this embodiment will be explained with reference to FIGS. 13 and 14.

An IP-combined gate array device 51′ according to this modification is obtained by applying the concept of the gate array matrix 6B′ shown in FIG. 6 to the third embodiment. In the IP-combined gate array device 51′, the CPU 53 and SRAM 54 can be mounted on the upper surface of a gate array unit 52′ like, e.g., the third embodiment. The ferroelectric RAM 55 as an IP is not directly mounted on the upper surface of the gate array unit 52′ and mounted through a gate array unit 61 as a semiconductor integrated circuit unit other than an IP.

For this reason, in the gate array unit 61, the bump pads 3 connected to the bump pads 3 of the gate array unit 52′ are provided, and through holes (conductive units) 44 which serve as bump pads on the upper surface of the gate array unit 61 when connected to the bump pads 3 of the gate array unit 52′ are formed. For example, the ferroelectric RAM 55 can be connected to the upper ends of the through holes 44 by the bumps 13. Other portions of the configuration are the same as those of the third embodiment.

If there is a need for one having a larger gate array scale than that of the gate array unit 52 in the third embodiment, this modification can meet the need by stacking the gate array units 61 with little increase in size (area).

With the structure in which the through holes (conductive units) 44 as conductive means which allow stacking of a memory device or the like in layers through the gate array unit 61 are formed, this modification can be implemented at lower cost than a case where conductive means is provided in a memory device as an IP. Other than that, this modification has almost the same effects as those of the third embodiment.

Although the ferroelectric RAM 55 as an example of an IP is connected to the upper surface of the gate array unit 61 by the bumps 13, a semiconductor integrated circuit element such as a gate array unit or complex logic unit other than an IP may be mounted. That is, an arbitrary semiconductor integrated circuit element including an IP can be mounted on the upper surface of the gate array unit 61.

This embodiment can also be applied to a configuration in which the gate array unit 52′ according to this modification is replaced with a complex logic unit.

Note that the present invention can also be applied to a case where as an IP (or IP unit) according to the present invention, a PLL (Phase Locked Loop) circuit, DSP (Digital Signal Processor), UART (Universal Asynchronous Receiver Transmitter), USB (Universal Serial Bus) controller, PCI (Peripheral Component Interconnect) controller, JPEG (Joint Photographic Experts Group) decoder LSI (Large Scale Integration), MPEG (Moving Picture Expert Group) decoder LSI, and the like are incorporated selectively or together, in addition to a CPU, SRAM, DRAM, ROM, flash memory, EEPROM, and ferroelectric RAM described above.

Having described the embodiments of the invention referring to the accompanying drawings, it should be understood that the present invention is not limited to those precise embodiments and various changes and modifications thereof could be made by one skilled in the art without departing from the spirit or scope of the invention as defined in the appended claims.

What is claimed is:

1. A semiconductor integrated circuit device including:
a semiconductor integrated circuit base in which one of a gate array unit and a complex logic unit is formed;
a connection unit provided on the semiconductor integrated circuit base; and
an IP (Intellectual Property) unit which is selectively connected through the connection unit and has a predetermined function.

2. The semiconductor integrated circuit device according to claim 1, wherein one of a second IP unit having a function different from the function of the IP unit to be connected integrally with the one of the gate array unit and the complex logic unit and a third IP unit having a function different from the function of the IP unit to be selectively connected through the connection unit can be connected to the semiconductor integrated circuit base.

3. The semiconductor integrated circuit device according to claim 2, wherein the second IP unit is formed in the semiconductor integrated circuit base, and the one of the gate array unit and the complex logic unit is formed around the second IP unit.

4. The semiconductor integrated circuit device according to claim 1, wherein the IP unit includes a CPU (Central Processing Unit) arranged at the center of the semiconductor integrated circuit base through the connection unit, and the one of the gate array unit and the complex logic unit is provided around the CPU.

5. The semiconductor integrated circuit device according to claim 1, wherein a semiconductor integrated circuit element having a second IP unit with a different function provided is mounted on the semiconductor integrated circuit base, to which the IP unit is selectively connected through the connection unit, to have a stacked structure.

6. The semiconductor integrated circuit device according to claim 3, wherein the second IP unit includes a CPU formed at the center of the semiconductor integrated circuit base, and the one of the gate array unit and the complex logic unit is provided around the CPU.

7. The semiconductor integrated circuit device according to claim 3, wherein the semiconductor integrated circuit base has an IP-combined gate array unit which has the gate array unit formed by closely laying a plurality of transistors around the second IP unit.

8. The semiconductor integrated circuit device according to claim 3, wherein the semiconductor integrated circuit base has an IP-combined complex logic unit which has the complex logic unit formed by closely laying a plurality of complex logic cells around the second IP unit.

9. The semiconductor integrated circuit device according to claim 1, wherein a plurality of IP units of different types and with different circuit scales can be connected to the connection unit.

10. The semiconductor integrated circuit device according to claim 9, wherein each of the IP units is one of an EEPROM (Electrically Erasable Programmable ROM), a DRAM (Dynamic RAM), an SRAM (Static Random Access Memory), a flash memory, and a ferroelectric RAM as a memory device.

11. The semiconductor integrated circuit device according to claim 1, wherein an I/O buffer is further provided in the semiconductor integrated circuit base.

12. The semiconductor integrated circuit device according to claim 1, wherein one of a memory device, a CPU, a PLL (Phase Locked Loop) circuit, a DSP (Digital Signal Processor), a UART (Universal Asynchronous Receiver Transmitter), a USB (Universal Serial Bus) controller, a PCI (Peripheral Component Interconnect) controller, a JPEG (Joint Photographic Experts Group) decoder LSI (Large Scale Integration), and an MPEG (Moving Picture Expert Group) decoder LSI is connected to the connection unit as the IP unit.

13. The semiconductor integrated circuit device according to claim 2, wherein one of a memory device, a CPU, a PLL circuit, a DSP, a UART, a USB controller, a PCI controller, a JPEG decoder LSI, and an MPEG decoder LSI is installed as the second IP unit or the third IP unit.

14. The semiconductor integrated circuit device according to claim 1, wherein the connection unit is one of a bump pad connected by a bump or a bonding pad connected by a bonding wire.

15. The semiconductor integrated circuit device according to claim 5, wherein one of a memory device, a CPU, a PLL circuit, a DSP, a UART, a USB controller, a PCI controller, a JPEG decoder LSI, and an MPEG decoder LSI is connected as the second IP unit to the semiconductor integrated circuit element.

16. The semiconductor integrated circuit device according to claim 1, further having a second semiconductor integrated circuit base, in which the circuit scale of one of a gate array unit and a complex logic unit is different from the circuit scale of the one of the gate array unit and the complex logic unit in the semiconductor integrated circuit base.

17. The semiconductor integrated circuit device according to claim 1, wherein a second connection unit which allows connection of a second IP unit to the semiconductor integrated circuit base is further provided in the IP unit, which is connected to the semiconductor integrated circuit base through the connection unit to have a stacked structure.

18. The semiconductor integrated circuit device according to claim 17, having a three-stage MCP (Multi Chip Package) structure in which the second IP unit is connected to the second connection unit including a through hole for conduction to form layers.

19. The semiconductor integrated circuit device according to claim 1, wherein the connection unit includes bump pads, and IP unit-side bump pads connected to the bump pads are provided along two parallel edges of the IP unit.

20. The semiconductor integrated circuit device according to claim 1, wherein the connection unit includes bump pads, and IP unit-side bump pads connected to the bump pads are provided along three edges of the IP unit.
